(19) United States
(12) Patent Application Publication
(10) Pub. No.: US 2012/0012979 A1
(43) Pub. Date: Jan. 19, 2012

(54) SEMICONDUCTOR CAPACITOR

(75) Inventors: David Vaclav Horak, Essex Junction, VT (US); Shom Ponoth, Hopewell Junction, NY (US); Hosadurga Shobha, Hopewell Junction, NY (US); Chih-Chao Yang, Albany, NY (US)

(73) Assignee: INTERNATIONAL BUSINESS MACHINES CORPORATION, Armonk, NY (US)

(21) Appl. No.: 12/837,121

(22) Filed: Jul. 15, 2010

(51) Int. Cl. H01L 29/92; H01L 21/02

(52) U.S. Cl. 257/532; 438/397; 257/E29.342; 257/E21.008

(57) ABSTRACT

An improved semiconductor capacitor and method of fabrication is disclosed. A nitride stack, comprising alternating sublayers of slow-etch and fast-etch nitride is deposited on a substrate. The nitride stack is etched via an anisotropic etch technique such as reactive ion etch. A wet etch then etches the nitride stack, forming a corrugated shape. The corrugated shape increases surface area, and hence increases the capacitance of the capacitor.

### FIELD OF THE INVENTION

The present invention relates to semiconductor integrated circuits, and more particularly to a semiconductor capacitor, and method for fabricating the same.

### BACKGROUND OF THE INVENTION

High Capacity Capacitors have been used in the semiconductor industry for years, in applications such as DRAM storage, protection from high energy environments, decoupling capacitors and many more.

As consumers are demanding products with more processing power, and smaller physical size, there is a need to improve the performance of various integrated circuits. Therefore, it is needed to have an improved semiconductor capacitor that has increased capacitance without a similar increase in substrate area required for its implementation.

### BRIEF DESCRIPTION OF THE DRAWINGS

The structure, operation, and advantages of the present invention will become further apparent upon consideration of the following description taken in conjunction with the accompanying figures (FIGs.). The figures are intended to be illustrative, not limiting.

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity. Block diagrams may not illustrate certain connections that are not critical to the implementation or operation of the present invention, for illustrative clarity.

In the drawings accompanying the description that follows, often both reference numerals and legends (labels, text descriptions) may be used to identify elements. If legends are provided, they are intended merely as an aid to the reader, and should not in any way be interpreted as limiting.

Often, similar elements may be referred to by similar numbers in various figures (FIGs) of the drawing, in which case typically the last two significant digits may be the same, the most significant digit(s) being the number of the drawing figure (FIG).

FIGS. 1-10 show a capacitor in accordance with an embodiment of the present invention at various steps in the fabrication process.

FIGS. 11-13 show a capacitor in accordance with an alternate embodiment of the present invention at various steps in the fabrication process.

FIGS. 14 and 15 are flowcharts indicating process steps for methods in accordance with embodiments of the present invention.

### SUMMARY

In one embodiment of the present invention, a semiconductor capacitor is provided, the capacitor comprises a base dielectric layer and a nitride stack disposed on the base dielectric layer. The nitride stack is comprised of a plurality of nitride sublayers, wherein a first subset of the nitride sublayers are comprised of fast-etch nitride, and wherein a second subset of the nitride sublayers are comprised of slow-etch nitride. Also, the nitride stack is comprised of alternating sublayers of fast-etch nitride and slow-etch nitride. A trench formed within the nitride stack is comprised of an interior surface having a corrugated shape. A first metal layer is disposed on the interior surface of the trench; a high-K dielectric layer is disposed on the first metal layer; and a second metal layer is disposed on the high-K dielectric layer, and fills the trench.

In another embodiment of the present invention, a semiconductor capacitor comprises a base dielectric layer. A nitride stack is disposed on the base dielectric layer. The nitride stack is comprised of a plurality of nitride sublayers. A first subset of the nitride sublayers is comprised of fast-etch nitride, and a second subset of the nitride sublayers is comprised of slow-etch nitride. The nitride stack is comprised of alternating sublayers of fast-etch nitride and slow-etch nitride. A trench is formed within the nitride stack comprising an interior surface having a corrugated shape. Each sublayer of fast-etch nitride has a thickness ranging from 2 to 3 times thicker than each sublayer of slow-etch nitride.

In another embodiment of the present invention, a method of fabricating a semiconductor capacitor is provided, comprises the steps of: forming a nitride stack of alternating sublayers of fast-etch nitride and slow-etch nitride on a base dielectric layer; depositing a lithographic mask on the nitride stack; forming a cavity in the nitride stack, the cavity comprising an interior surface; performing a wet etch on the cavity; depositing a first capacitor metal on the interior surface of the cavity; depositing a high-K dielectric layer on the first capacitor metal; and depositing a second capacitor metal on the high-K dielectric layer.

### DETAILED DESCRIPTION

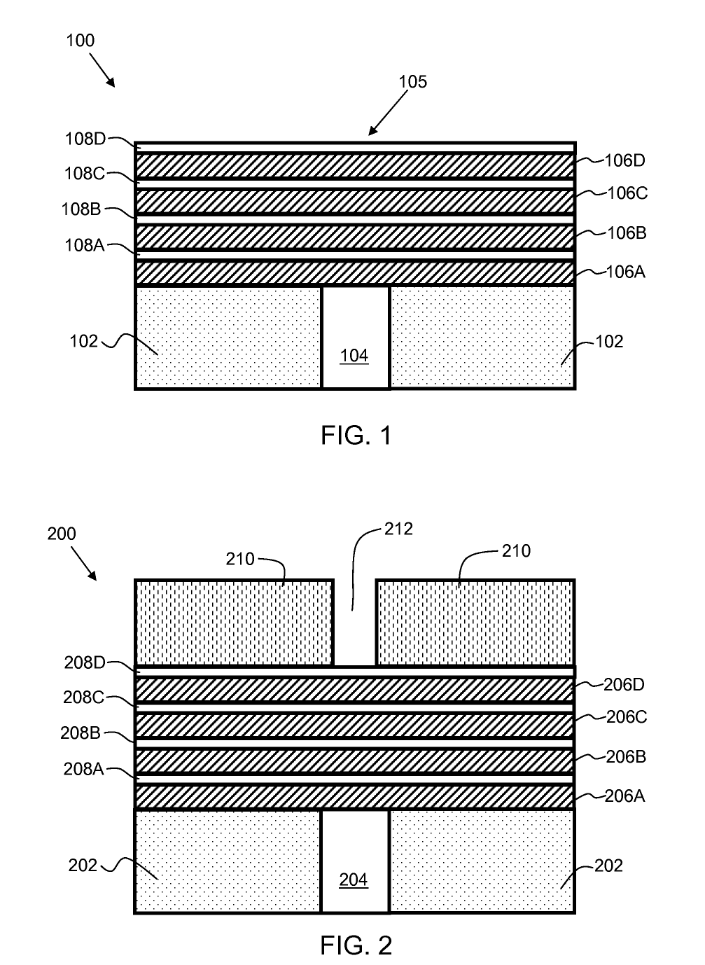

FIG. 1 shows a semiconductor structure 100 at an intermediate processing step. Base Dielectric layer 102 is typically an interlayer dielectric layer (ILD). Within dielectric layer 102 is metal contact 104, which forms a first contact for a capacitor. In one embodiment, metal contact 104 is comprised of tungsten. In another embodiment, metal contact 104 is comprised of doped polysilicon. Disposed on base dielectric layer 102 is a nitride stack 105 which is comprised of a plurality of alternating fast-etch (106A-106D) and slow-etch (108A-108D) nitride sublayers. Each layer with a 106 reference number is a fast-etch nitride sublayer. Each layer with a 108 reference number is a slow-etch nitride sublayer.

The fast and slow etch nitrides may be referred to by the generic reference number (without an accompanying letter) when referred to in a general sense. A letter suffix will be used when discussing a specific nitride sublayer. Nitride layer 106A is deposited onto base dielectric layer 102. Nitride layer 108A is disposed onto nitride layer 106A. This structure can be repeated a number of times to form the nitride stack 105. The nitride stack 105 in the embodiment shown in FIG. 1 has four layers of fast-etch nitride interspersed with four layers of slow-etch nitride. However, embodiments of the present invention may use more or less layers of fast and slow etch nitride layers. The alternating nitride layers are deposited in a single deposition step where the hydrogen content is varied by changing deposition conditions inside of the deposition reactor. The differing hydrogen content causes the nitride layers to etch at different rates when undergoing a wet etch.

Slow-etch nitride 108 is a typical nitride such as silicon nitride (Si3N4) having a low hydrogen content. Fast-etch nitride 106 is also Si3N4, but contains higher levels of hydrogen than slow-etch nitride 108. The increased hydrogen content in the fast-etch oxide 106 results in a much faster etch rate when subjected to a wet etch using an etchant comprised of HF. This will be used to create a capacitor with increased surface area, hence increased capacitance.

The increased hydrogen content in the fast-etch nitride comes from inclusion of a higher percentage of NH bonds. The percentage of NH bonds varies inversely with film density. Thus, the slow-etch nitride has a higher density than the fast-etch nitride.

In one embodiment, the density of the slow-etch nitride ranges from about 2.6 g/cc to about 2.8 g/cc (grams/cubic centimeter), and in a particular embodiment, the density is about 2.62 g/cc, and the fast-etch nitride has a density ranging from about 2.0 g/cc to about 2.4 g/cc. Other embodiments have a fast-etch nitride with a density lower than 2.0 g/cc.

The alternating layers of fast-etch and slow-etch nitrides can be formed by alternating deposition conditions in real time using well-known processes such as CVD or PECVD. In one embodiment, in order to form the fast-etch nitride film, the deposition conditions are modified by increasing the flow ratio of NH₃ to SiH₄ flow to ratio of less than 0.25, and decreasing the power during the deposition to less than 40% of the power that is used for the slow-etch nitride film. U.S. Pat. No. 4,960,656, included herein by reference, discloses a method of altering hydrogen content in a nitride layer.

FIG. 2 shows a semiconductor structure 200 at a subsequent intermediate processing step. As stated previously in this disclosure, similar elements may be referred to by similar numbers in various figures (FIGs) of the drawing, in which case typically the last two significant digits may be the same. For example, base dielectric layer 102 of FIG. 1 is similar to base dielectric layer 202 of FIG. 2. In this process step, masking layer of photoresist (a.k.a mask) 210 is deposited on the top nitride layer 208D. Using industry-known lithographic methods, a void 212 is formed above the nitride layer 208D where a cavity or trench will be formed.

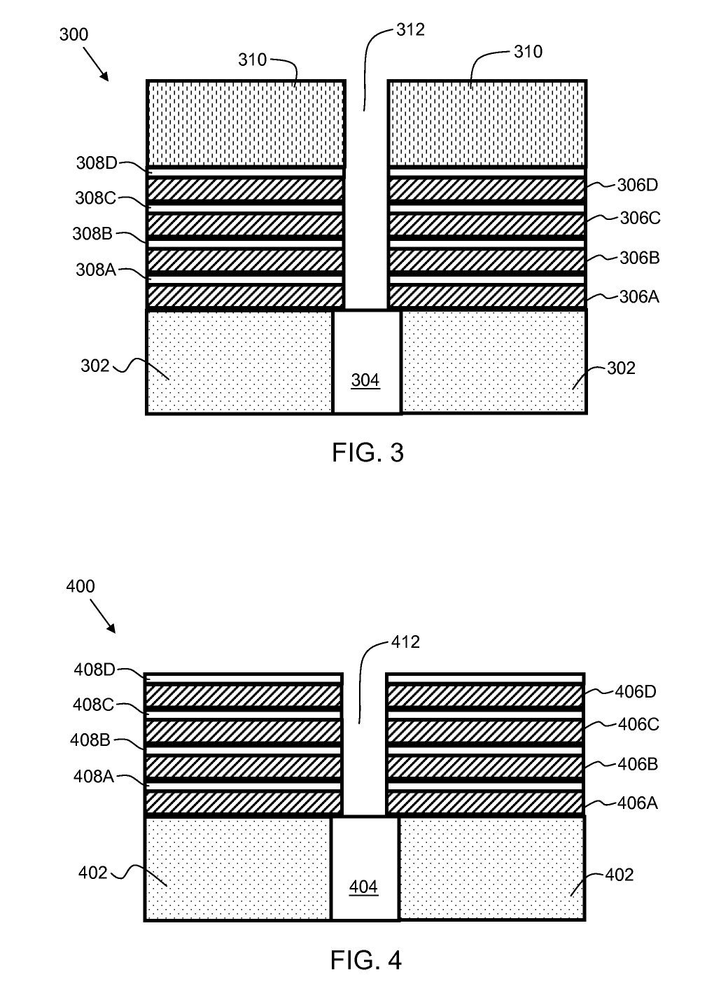

FIG. 3 shows a semiconductor structure 300 at a subsequent intermediate processing step. In this processing step, a reactive ion etch (RIE) is applied to create void 312, which extends from the top of semiconductor structure 300 to first metal contact 304. Note that perfect alignment is not required as long as part of the opening lands on the contact.

FIG. 4 shows a semiconductor structure 400 at a subsequent intermediate processing step. In this processing step, the mask layer is removed, typically via a resist snip process, well known in the industry.

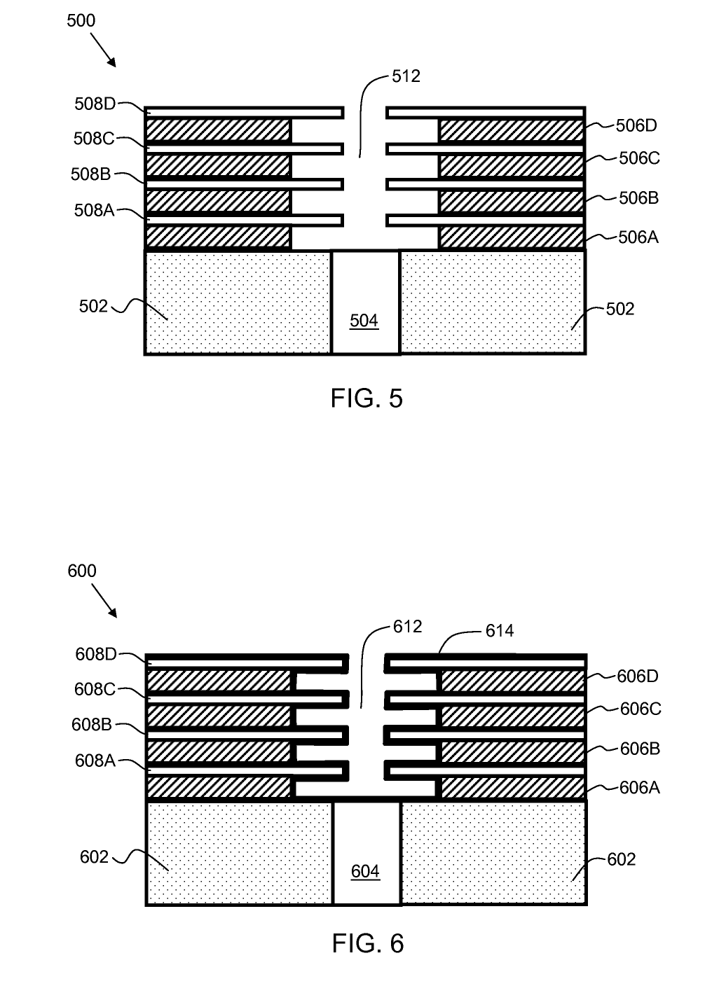

FIG. 5 shows a semiconductor structure 500 at a subsequent intermediate processing step. In this processing step, a wet etch using HF (hydrofluoric acid) is applied to semiconductor structure 500. Because of the different properties of the fast-etch nitride 506 and the slow-etch nitride 508, more of the slow-etch nitride 508 remains, forming a corrugated shape within trench 512. Namely the increased hydrogen content in the fast-etch nitride 506 provides an etch rate of as much as 100 times that of slow-etch nitride 508. In one embodiment, the etch rate difference of the fast-etch nitride is 100 to 200 times the rate of the slow-etch nitride.

In the embodiment shown in FIG. 5, fast-etch nitride 506 is thicker than slow-etch nitride 508. This provides the advantage of further increasing surface area within trench 512, as the fast-etch nitride, being thicker, exposes more surface area when etched. In one embodiment, fast-etch nitride 506 is 2 to 3 times thicker than slow-etch nitride 508. In one embodiment, slow-etch nitride 508 ranges in thickness from about 70 angstroms to about 140 angstroms, and fast-etch nitride 506 ranges in thickness from about 200 angstroms to about 250 angstroms.

Optionally, after the wet etch, a densifying anneal may be performed. In one embodiment, this step is performed at a temperature in the range of about 900 to about 1050 degrees Centigrade, for a duration ranging from Spike (about 1 second) to about 60 seconds. In another embodiment, well-suited for BEOL applications, the temperature is limited to 400 degrees Centigrade and the duration is less than 1 hour. The densifying anneal serves the purpose of driving out the excess hydrogen thereby decreasing the sensitivity of the stack during other steps in the fabrication process, such as HF pre-clean processes.

FIG. 6 shows a semiconductor structure 600 at a subsequent intermediate processing step. In this processing step, a first metal layer 614 is applied to the interior surface of trench 612. In one embodiment, the first metal layer 614 may be one of ruthenium or tantalum. Metal layer 614 is preferably applied via atomic layer deposition (ALD). ALD deposits layers with good conformal properties, even with the high aspect ratios within trench 612, and allows metal layer 614 to be uniformly applied to the interior surface of trench 612.

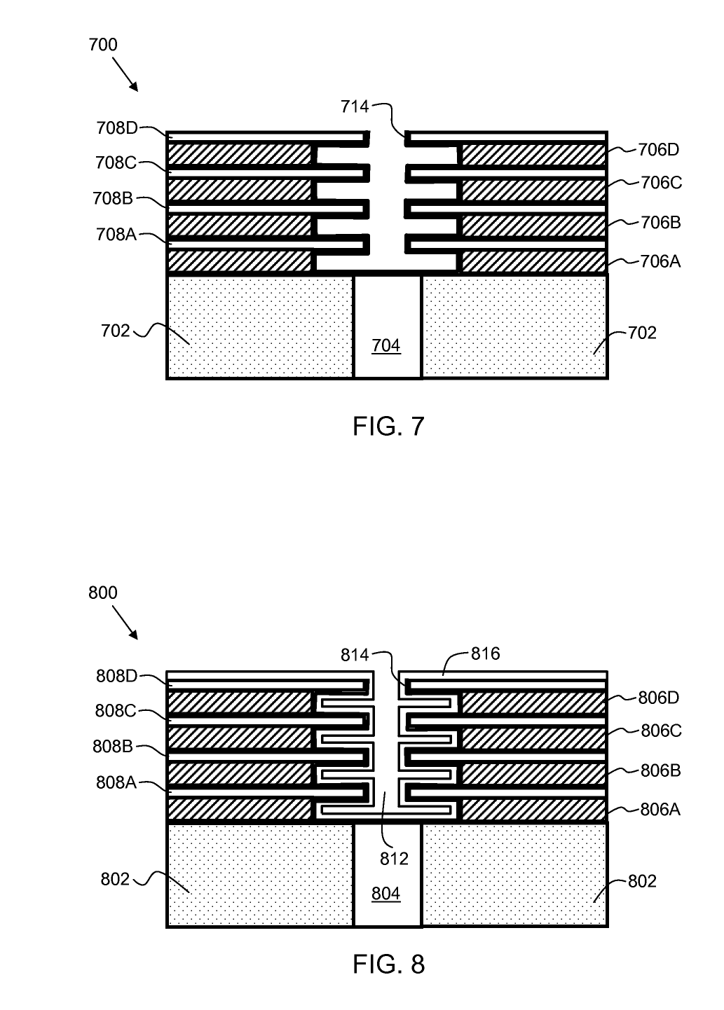

FIG. 7 shows a semiconductor structure 700 at a subsequent intermediate processing step. In this processing step, the portion of metal layer 614 that was on nitride layer 608D (see FIG. 6) is removed. In one embodiment, the removal of that portion of metal layer is performed via chemical mechanical polish (CMP). In particular, a fixed abrasive CMP process, which does not use any slurry, is well suited for this step. The use of slurry is preferably avoided since slurry could potentially clog the trench 714, causing fabrication defects.

FIG. 8 shows a semiconductor structure 800 at a subsequent intermediate processing step. In this processing step, a high-K dielectric layer 816 is applied to the interior surface of trench 812, as well as to the top surface of topmost nitride layer 808D. In one embodiment, high-K dielectric layer 816 is comprised of hafnium oxide (HfO₂). In another embodiment, hafnium silicate is used as the high-K dielectric layer 816. In yet another embodiment, zirconium oxide is used as the high-K dielectric 816. In a preferred embodiment, the high-K dielectric layer 816 ranges in thickness from about 20 angstroms to about 50 angstroms, and is deposited via ALD. The high-K dielectric 816 preferably has a dielectric constant preferably ranging from about 15 to 20, but the dielectric constant of the high-K dielectric 816 can exceed 20.

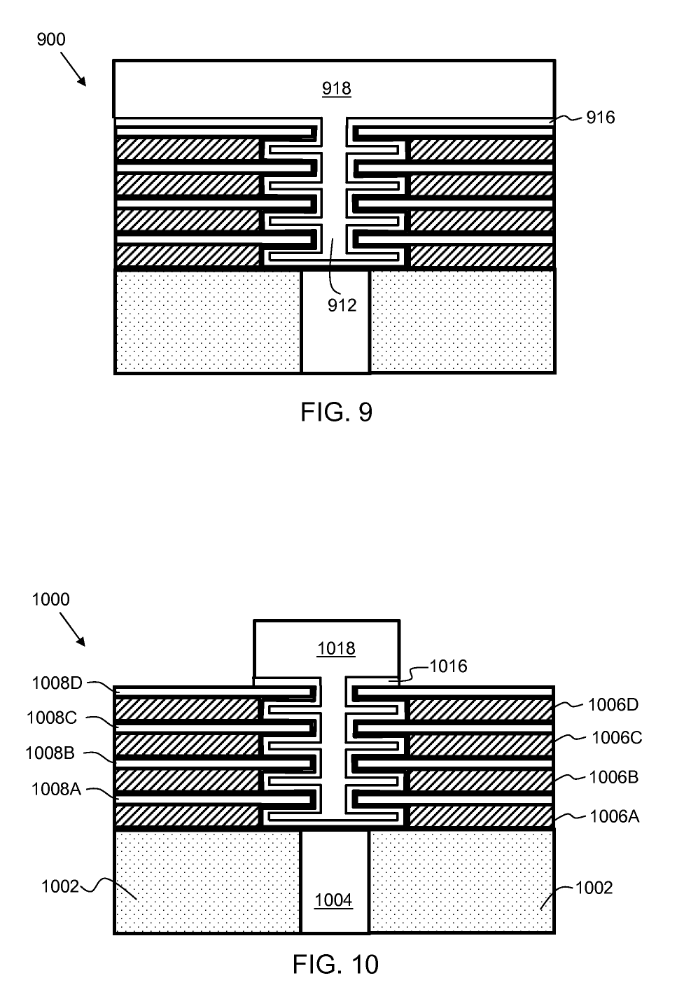

FIG. 9 shows a semiconductor structure 900 at a subsequent intermediate processing step. In this processing step, a second capacitor metal 918 is deposited on semiconductor structure 918, and enters trench 912. In one embodiment, second capacitor metal 918 is comprised of ruthenium or tantalum and is deposited via ALD.

FIG. 10 shows a semiconductor structure 1000 at a subsequent intermediate processing step. In this processing step, second capacitor metal 1018 and high-K dielectric 1016 are formed by etching away excess material (compare with 916 and 918 of FIG. 9) such that only a portion of the second capacitor metal remains, which forms a second contact for the capacitor.

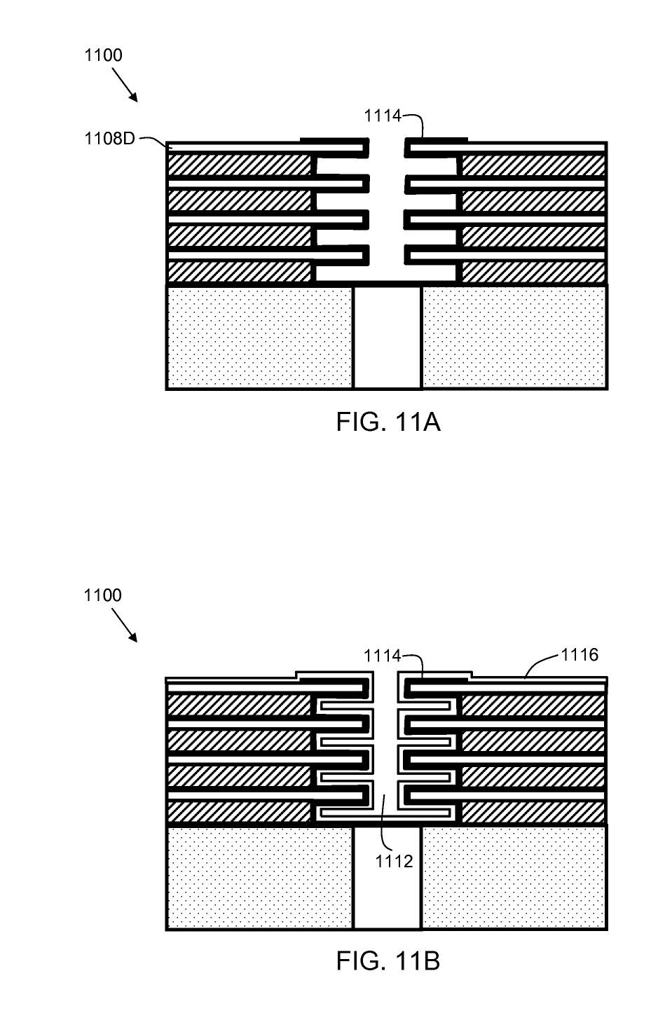

FIGS. 11-13 show a capacitor in accordance with an alternate embodiment of the present invention at various steps in the fabrication process. FIG. 11A shows a semiconductor structure 1100 of the alternate embodiment at a subsequent intermediate processing step which follows from FIG. 6. In this process step, first capacitor metal 1114 is lithographically etched, such that only a portion of first capacitor metal 1114 is present on the top surface of nitride layer 1108D. In this embodiment, the step of CMP of the first capacitor metal is eliminated (compare with FIG. 7). FIG. 11B shows a semiconductor structure 1100 of the alternate embodiment at a subsequent intermediate processing step. In this processing step, high-K dielectric 1116 is deposited in the trench 1112, as well as on the top surface of semiconductor structure 1100. The high-K dielectric 1116 is preferably deposited via ALD.

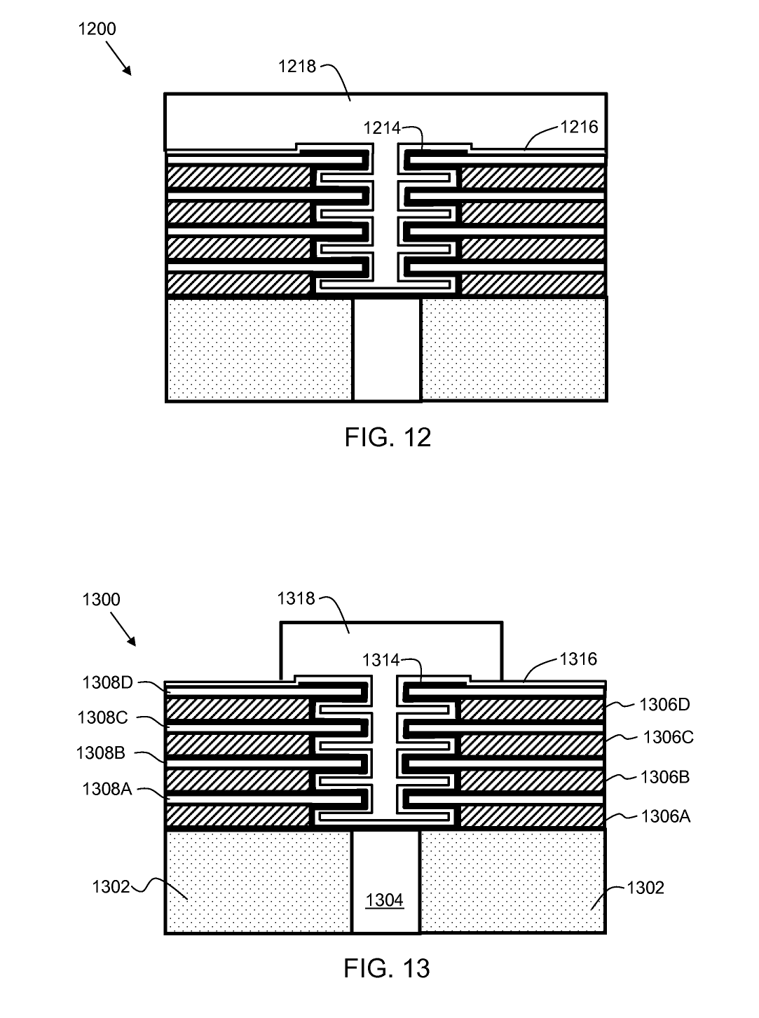

FIG. 12 shows a semiconductor structure 1200 of the alternate embodiment at a subsequent intermediate processing step. In this processing step, second capacitor metal 1218 is applied, preferably via ALD, similar to as described for FIG. 9.

FIG. 13 shows a semiconductor structure 1300 of the alternate embodiment at a subsequent intermediate processing step. In this processing step, the second capacitor metal 1318 is etched to form a second contact for the capacitor. The high-K dielectric 1316 remains on the top surface (above nitride layer 1308D) outside of the area covered by second capacitor metal 1318 in this embodiment, as compared with the embodiment shown in FIG. 10, which does not have high-K dielectric 1016 on the top surface of the nitride layer 1008D outside of the area covered by second capacitor metal 1018.

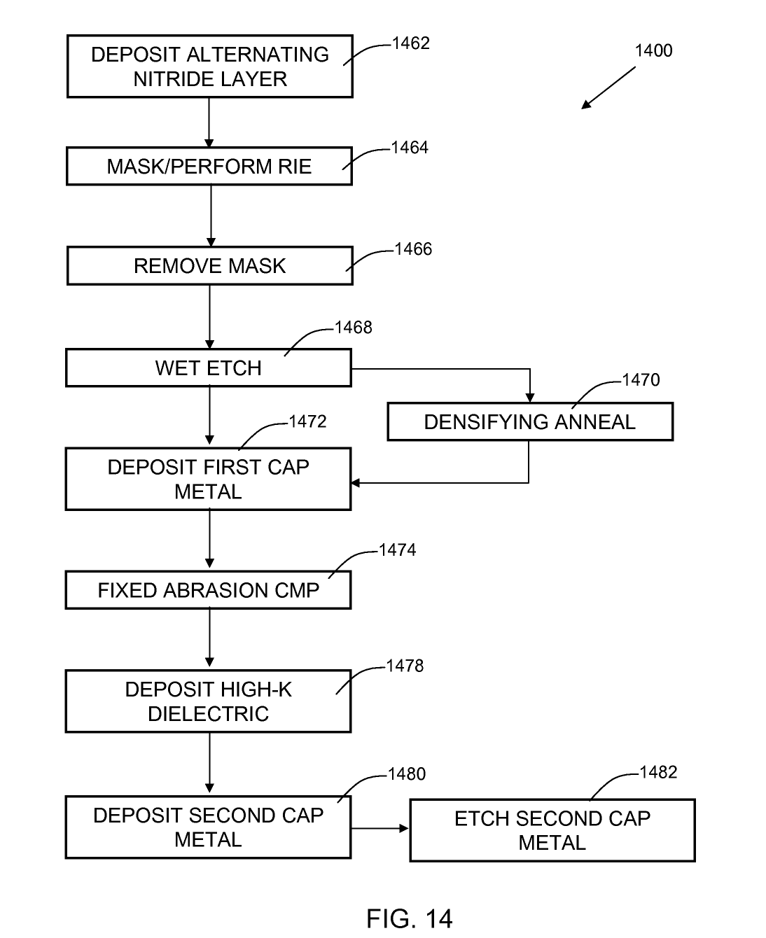

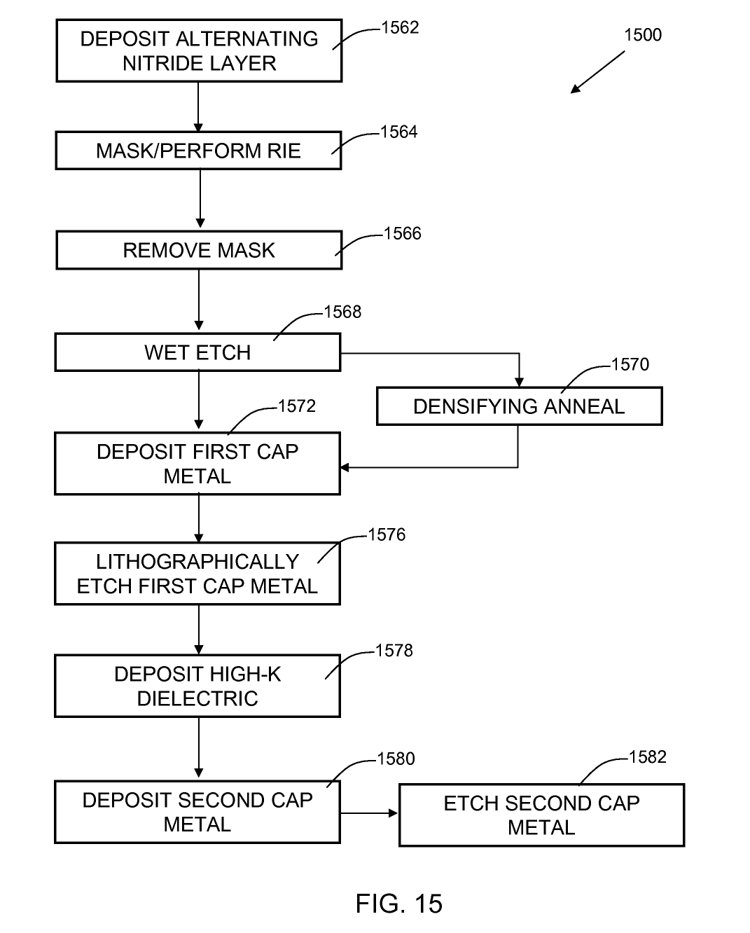

FIGS. 14 and 15 are flowcharts indicating process steps for methods in accordance with embodiments of the present invention. FIG. 14 shows flowchart 1400, which illustrates process steps for a method in accordance with an embodiment of the present invention. In process step 1462, an alternating layer of two types of nitrides is deposited. One sublayer is of a slow-etch nitride composition, with a very low wet etch rate. In one embodiment, the density of the slow-etch nitride is about 2.62 g/cc. Another sublayer of nitride is of a lower density, and thus, contains higher levels of NH bonds, which increases the etch rate. The pattern of the first and second sublayers may be repeated numerous times to form a nitride stack. In process step 1464 a mask (photoresist) is applied, and then a reactive ion etch (RIE) is performed to form a trench into the nitride stack. In process step 1466 the mask is removed via industry-standard methods, such as stripping or etching. In process step 1468 a wet etch is performed, preferably with HF (Hydrofluoric acid). The HF has a considerably different etch rate on the various sublayers of the nitride layer stack, forming a corrugated shape (first shown in FIG. 5). Optionally, a densifying anneal is performed at process step 1470. This anneal serves to drive out the Hydrogen, and it in effect “freezes” the corrugated shape, as the difference in HF etch rates between the last and slow etch nitrides is reduced considerably. Therefore the corrugated shape is not very much affected by other fabrication steps, such as precleans before the film depositions. The anneal can be used so long as the wafer substrate can tolerate the temperature exposure. In process step 1472, the first capacitor metal is deposited, preferably via ALD. In process step 1474, a fixed abrasive chemical mechanical polish (CMP) is performed. Process step 1474 preferably does not use slurry, which could potentially clog the trench or leave residues behind in the openings. In process step 1478, the high-K dielectric is deposited, preferably via ALD. In one embodiment, the high-K dielectric deposited during process step 1478 is hafnium oxide. In process step 1480, the second capacitor metal is deposited. In one embodiment, the metal deposited during process step 1480 is ruthenium or tantalum. However, other metals with sufficiently low resistivity for the given application may also be used. In process step 1482, the second capacitor metal is etched to form the second plate (electrode) of the capacitor.

FIG. 15 shows flowchart 1500, which illustrates process steps for a method in accordance with an embodiment of the present invention. In process step 1562, the nitride stack of alternating sublayers is thrilled. In process step 1564 a mask (photoresist) is applied and exposed, and then a reactive ion etch (RIE) is performed to form a trench into the nitride stack. In process step 1566 the mask is removed via industry-standard methods, such as stripping or etching. In process step 1568 a wet etch is performed, preferably with HF (Hydrofluoric acid). The HF has a considerably different etch rate on the various sublayers of the nitride layer stack, forming a corrugated shape (first shown in FIG. 5). Optionally, a densifying anneal is performed at process step 1570. In process step 1572, the first capacitor metal is deposited, preferably via ALD. In process step 1576, the first capacitor metal is lithographically etched. This is in contrast to the embodiment outlined in FIG. 14, which uses a CMP process to remove a portion of the first capacitor metal. The remainder of the process steps in FIG. 15 is similar to those in FIG. 14. In process step 1578, the high-K dielectric is deposited, preferably via ALD or any other nearly completely conformal deposition process. In one embodiment, the high-K dielectric deposited during process step 1578 is hafnium oxide. In process step 1480, the second capacitor metal is deposited. In process step 1582, a lithographic process defines the edges or the second capacitor metal, which is etched to form the second plate (electrode) of the capacitor.

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, circuits, etc.) the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

What is claimed is:

1. A semiconductor capacitor comprising:
a base dielectric layer;
a nitride stack disposed on the base dielectric layer, the nitride stack comprised of a plurality of nitride sublayers, wherein a first subset of the nitride sublayers are comprised of fast-etch nitride, and wherein a second subset of the nitride sublayers are comprised of slow-etch nitride, and wherein the nitride stack is comprised of alternating sublayers of fast-etch nitride and slow-etch nitride:
a trench formed within the nitride stack, the trench comprising an interior surface having a corrugated shape;
a first metal layer, the first metal layer disposed on the interior surface of the trench;
a high-K dielectric layer disposed on the first metal layer; and
a second metal layer disposed on the high-K dielectric layer, and filling the trench.

2. The semiconductor capacitor of claim 1, wherein the slow-etch nitride has a density ranging from about 2.6 g/cc to about 2.8 g/cc.

3. The semiconductor capacitor of claim 1, wherein the fast-etch nitride has a density ranging from about 2.0 g/cc to about 2.4 g/cc.

4. The semiconductor capacitor of claim 1, wherein the first metal layer is comprised of a material selected from the group consisting of ruthenium and tantalum.

5. The semiconductor capacitor of claim 1, wherein the high-K dielectric layer is comprised of a material selected from the group consisting of hafnium oxide, hafnium silicate, and zirconium oxide.

6. The semiconductor capacitor of claim 1, wherein each sublayer of fast-etch nitride has a thickness ranging from about 200 angstroms to about 250 angstroms and wherein each sublayer of slow-etch nitride has a thickness ranging from about 70 angstroms to about 140 angstroms.

7. A semiconductor capacitor comprising:
a base dielectric layer;
a nitride stack disposed on the base dielectric layer, the nitride stack being comprised of a plurality of nitride sublayers, wherein a first subset of the nitride sublayers is comprised of fast-etch nitride, and wherein a second subset of the nitride sublayers is comprised of slow-etch nitride, and wherein the nitride stack is comprised of alternating sublayers of fast-etch nitride and slow-etch nitride; and
a trench formed within the nitride stack, the trench comprising an interior surface having a corrugated shape; and
wherein each sublayer of fast-etch nitride has a thickness ranging from 2 to 3 times thicker than each sublayer of slow-etch nitride.

8. The semiconductor capacitor of claim 7, wherein the slow-etch nitride has a density ranging from about 2.6 g/cc to about 2.8 g/cc and wherein the fast-etch nitride has a density ranging from about 2.0 g/cc to about 2.4 g/cc.

9. The semiconductor capacitor of claim 8, wherein each sublayer of fast-etch nitride has a thickness ranging from about 200 angstroms to about 250 angstroms.

10. A method of fabricating a semiconductor capacitor, comprising the steps of:
forming a nitride stack of alternating sublayers of fast-etch nitride and slow-etch nitride on a base dielectric layer;
depositing a lithographic mask on the nitride stack;
forming a cavity in the nitride stack, the cavity comprising an interior surface;
performing a wet etch on the cavity;
depositing a first capacitor metal on the interior surface of the cavity;
depositing a high-K dielectric layer on the first capacitor metal; and
depositing a second capacitor metal on the high-K dielectric layer.

11. The method of claim 10, further comprising the step of performing a densifying anneal.

12. The method of claim 11, wherein the densifying anneal is performed at a temperature range of about 950 degrees Centigrade to about 1050 degrees Centigrade.

13. The method of claim 10, wherein the step of forming a cavity in the nitride stack is performed via reactive ion etch.

14. The method of claim 10, wherein the step of performing a wet etch on the cavity comprises applying an etchant of hydrofluoric acid.

15. The method of claim 10, wherein the step of depositing a first capacitor metal on the interior surface of the cavity is performed via atomic layer deposition.

16. The method of claim 10, wherein the step of depositing a high-K dielectric layer is performed via atomic layer deposition.

17. The method of claim 10, wherein the step of depositing a second capacitor metal is performed via atomic layer deposition.

18. The method of claim 10, further comprising the step of lithographically etching the first capacitor metal after the step of depositing the first capacitor metal.

19. The method of claim 10, further comprising the step of performing a fixed abrasive chemical mechanical polish after the step of depositing the first capacitor metal.

20. The method of claim 10, wherein the step of forming a nitride stack of alternating sublayers of fast-etch nitride and slow-etch nitride on a base dielectric layer comprises the steps of:
depositing at least one layer of nitride having a density ranging from about 2.6 g/cc to about 2.8 g/cc; and
depositing at least one layer of nitride having a density ranging from about 2.0 g/cc to about 2.4 g/cc.
